(19) United States
(12) Patent Application Publication
(10) Pub. No.: US 2026/0238196 A1
(43) Pub. Date: Aug. 13, 2026

(54) Complementary Frequency Multiplying Circuitry

(71) Applicant: Apple Inc., Cupertino, CA (US)

(72) Inventors: Rong Jiang, San Diego, CA (US); Chen Zhai, San Diego, CA (US); Chunwei Chang, San Jose, CA (US); Jongmin Park, San Diego, CA (US)

(21) Appl. No.: 19/051,694

(22) Filed: Feb. 12, 2025

(51) Int. Cl. H03K 5/00; H03K 17/687

(52) U.S. Cl. CPC H03K 5/00006; H03K 17/6871

(57) ABSTRACT

A frequency multiplying circuit can include a first pull-down transistor configured to receive an input signal having a fundamental frequency, a first pull-up transistor configured to receive the input signal, and a coil having a first terminal coupled to the first pull-down transistor and having a second terminal coupled to the first pull-up transistor. The coil can be coupled to a differential output at which an output signal having an output frequency that is a multiple of the fundamental frequency is produced. The frequency multiplying circuit can include one or more additional pull-down transistors and one or more additional pull-up transistors. The coil can be part of an output transformer. One or more adjustable capacitors can be coupled to the output transformer.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless communications circuitry in the wireless communications circuitry uses the antennas to receive and transmit radio-frequency signals.

The wireless communications circuitry can include a transceiver having one or more mixers. A mixer in the transmit path can be used to modulate signals from a baseband frequency to a radio frequency, whereas a mixer in the receive path can be used to demodulate signals from the radio-frequency to the baseband frequency. Mixers receive clock signals generated from local oscillator circuitry. It can be challenging to design satisfactory local oscillator circuitry for an electronic device.

### SUMMARY

An aspect of the disclosure provides a frequency multiplier that includes a first pull-down transistor configured to receive an input signal having a given frequency, a first pull-up transistor configured to receive the input signal, and a coil having a first terminal coupled to the first pull-down transistor and having a second terminal coupled to the first pull-up transistor. The coil can be coupled to a differential output at which an output signal having an output frequency that is a multiple of the given frequency is produced. The frequency multiplier can further include a second pull-down transistor coupled in parallel with the first pull-down transistor, a second pull-up transistor coupled in parallel with the first pull-up transistor, and a capacitor having a first terminal coupled to the first terminal of the coil and having a second terminal coupled to the second terminal of the coil. The coil can have a center tap terminal configured to receive a bias voltage equal to half of a positive power supply voltage.

An aspect of the disclosure provides a frequency multiplier configured to multiply a frequency of an oscillating signal and that includes a first pull-down transistor configured to receive the oscillating signal, a first pull-up transistor configured to receive the oscillating signal, and a transformer having a first terminal coupled to the first pull-down transistor and having a second terminal coupled to the first pull-up transistor. The frequency multiplier can further include a second pull-down transistor coupled in parallel with the first pull-down transistor and a second pull-up transistor coupled in parallel with the first pull-up transistor. The transformer can include: a primary coil having a first terminal coupled to a drain terminal of the first pull-down transistor and having a second terminal coupled to a drain terminal of the first pull-up transistor; and a secondary coil having a first terminal coupled to a first output terminal and having a second terminal coupled to a second output terminal.

An aspect of the disclosure provides a frequency multiplying circuitry that includes a coil, a first pair of pull-down transistors configured to receive a first differential input signal, and a second pair of pull-down transistors configured to receive a second differential input signal different than the first differential input signal. The frequency multiplying circuitry can further include a first pair of pull-up transistors configured to receive the first differential input signal and a second pair of pull-up transistors configured to receive the second differential input signal. The second differential input signal can be shifted with respect to the first differential input signal by 90 degrees.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having oscillator circuitry in accordance with some embodiments.

FIG. 3 is a diagram of an illustrative oscillator having a frequency multiplying circuit in accordance with some embodiments.

FIG. 4 is a circuit diagram of an illustrative complementary frequency multiplier circuit in accordance with some embodiments.

FIG. 5 is circuit diagram of an illustrative complementary frequency multiplier circuit having an output transformer in accordance with some embodiments.

FIG. 6 is a circuit diagram of an illustrative frequency quadrupling circuit in accordance with some embodiments.

### DETAILED DESCRIPTION

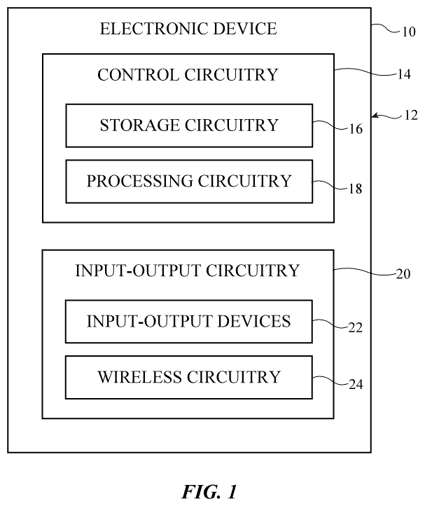

An electronic device such as electronic device 10 of FIG. 1 may be provided with wireless circuitry. The wireless circuitry can include one or more mixers and oscillator circuitry configured to generate oscillating signals or clock signals that are supplied to the one or more mixers. The oscillator circuitry can include one or more frequency multipliers. A frequency multiplier can be configured to multiply the frequency of an incoming oscillating signal by a factor of two and is therefore sometimes referred to as a frequency doubling circuit.

The frequency doubling circuit can include a pair of differential pull-down transistors, a pair of differential pull-up transistors, and a coil coupled between the pair of differential pull-down transistors and the pair of the differential pull-up transistors. The coil can optionally be part of an output transformer. Configured in this way, a differential output signal can be provided without requiring a balun, and current flowing through the pull-up transistors can concurrently flow through the pull-down transistors. Reusing current in a frequency doubling circuit can be technically advantageous and beneficial to augment the output (voltage) swing without increasing power consumption. Alternatively, the power consumption can be reduced by half at the same output swing. Moreover, a reduced level of stress can be distributed between the pull-up and pull-down transistors, which improves device reliability.

Electronic device 10 of FIG. 1 can include such types of frequency multipliers and may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

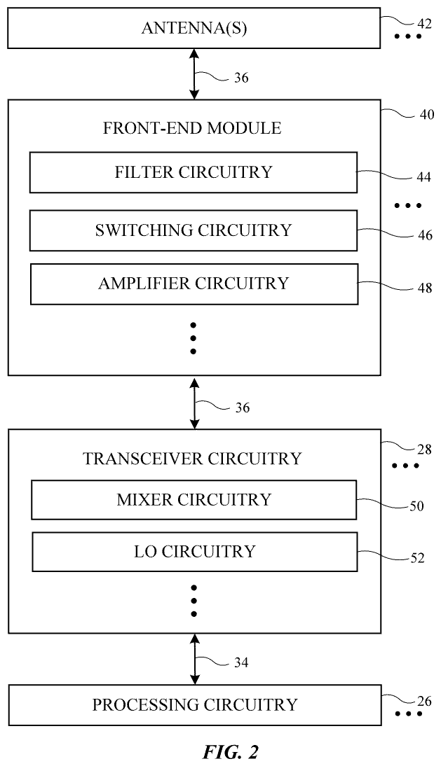

FIG. 2 is a diagram showing illustrative components within wireless circuitry 24. Wireless circuitry 24 can include, as part of oscillator circuitry 52, one or more phase noise filters with improved phase noise suppression capabilities. As shown in FIG. 2, wireless circuitry 24 may include one or more processors such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be baseband processing circuitry, one or more application processor, one or more digital signal processor, one or more microcontroller, one or more microprocessor, one or more central processing unit (CPU), one or more programmable device, a combination of these circuits, and/or other types of processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be interposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. The various front-end module components may be integrated into a single integrated circuit chip or may be formed as part of multiple integrated circuit chips.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide digital signals to transceiver 28 over path 34. Transceiver 28 may further include circuitry for converting the baseband signals received from processing circuitry 26 into corresponding intermediate frequency or radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front-end module 40. Transceiver 28 may include circuitry for converting the received radio-frequency signals into corresponding intermediate frequency or baseband signals. For example, transceiver 28 may use mixer circuitry 50 for downconverting (or demodulating) the received radio-frequency signals to baseband frequencies prior to conveying the received signals to processing circuitry 26 over path 34.

Transceiver 28 can include local oscillator circuitry such as local oscillator (LO) circuitry 52. Local oscillator circuitry 52 can generate oscillator or oscillating signals that mixer circuitry 50 uses to modulate transmitting signals from baseband frequencies to radio frequencies and/or to demodulate the received signals from radio frequencies to baseband or intermediate frequencies. Local oscillator circuitry 52 can generally include phase-locked loop (PLL) or delay-locked loop (DLL) circuitry configured to generate the oscillating signals being fed to inputs of mixer circuitry 50. Other types of oscillator circuitry 52 can also be employed.

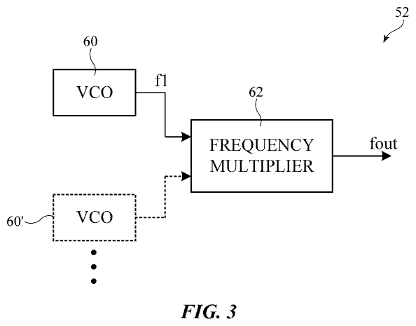

FIG. 3 is a diagram of an illustrative oscillator 52 having a frequency multiplying circuit 62 in accordance with some embodiments. Frequency multiplying circuit 62 is sometimes referred to as a frequency multiplier. As shown in FIG. 3, frequency multiplier 62 can have an input configured to receive an oscillating signal from a voltage-controlled oscillator (VCO) 60. The oscillating signal output from VCO 60 can have an oscillation frequency f1. Frequency multiplier 62 can be configured to multiply frequency f1 of the incoming oscillating signal by a factor of N, where N is equal to 2, 3, 4, 5, 5-10, 10-100, greater than 100, or other integer value. If desired, N can be a non-integer value such as 2.5, 4.1, etc. In other words, frequency multiplier 62 can output a corresponding oscillating signal having a multiplied/scaled frequency fout, where fout is equal to N*f1. In the case where N is equal to 2, frequency multiplying circuit 62 can be referred to as a frequency doubler. In the case where N is equal is equal to 3, frequency multiplying circuit 62 can be referred to as a frequency tripler. In the case where N is equal is equal to 4, frequency multiplying circuit 62 can be referred to as a frequency quadrupler. Integer N can thus sometimes be referred to and defined herein as a frequency multiplication/scaling factor.

In certain embodiments, frequency multiplier 62 can have one or more additional inputs configured to receive additional oscillating signals. In the example of FIG. 3, frequency multiplier 62 can have a second input configured to receive an oscillating signal from an additional VCO 60′. The oscillating signal output from additional VCO 60′ can be equal to or different than frequency f1. Frequency multiplier 62 can be configured to multiply the oscillating signal output from VCO 60′ using the same multiplying factor N that it uses for scaling frequency f1. The example of FIG. 3 in which oscillator 52 includes one frequency multiplier 62 is illustrative. If desired, oscillator 52 can include more than one frequency multiplier 62, each with the same or different frequency multiplication factors, and each having one or more inputs.

A conventional frequency multiplier includes a first n-channel transistor, a second n-channel transistor shorted to the first n-channel transistor, and a single-ended inductor shorted to the first and second n-channel transistors. In particular, the inductor has a first terminal coupled to drain terminals of the first and second n-channel transistors and a second terminal shorted to a positive power supply line. Arranged in this way, the first terminal of the inductor can serve as a single-ended output terminal. Here, a balun is required to convert the single-ended output of the frequency multiplier to a differential output.

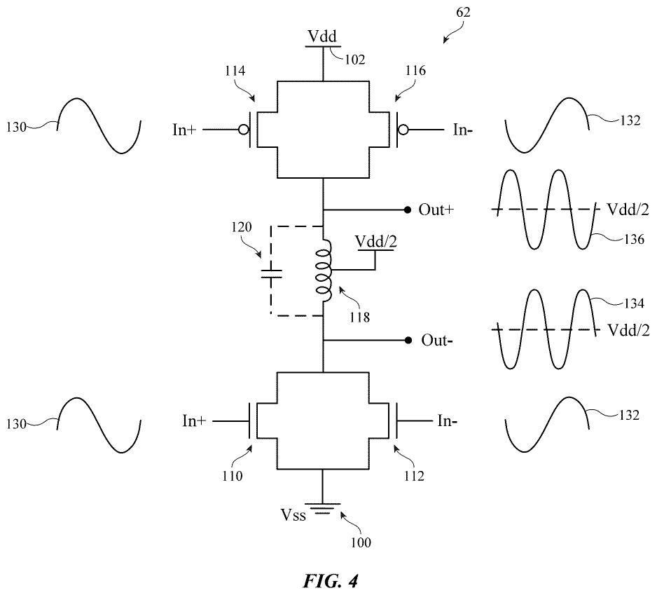

In accordance with an embodiment, FIG. 4 is a circuit diagram of frequency multiplier circuit 62 of the type described in connection with FIG. 3. As shown in FIG. 4, frequency multiplier circuit 62 can include pull-down transistors 110 and 112, pull-up transistors 114 and 116, and a coil 118. The pull-down transistors 110 and 112 can be n-type (n-channel) metal-oxide-semiconductor or “NMOS” transistors. Transistor 110 can have a source terminal coupled to a ground power supply line 100 (e.g., a ground power supply terminal on which a ground voltage Vss is provided), a gate terminal coupled to a first input terminal In+, and a drain terminal. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Similarly, transistor 112 can have a source terminal coupled to the ground power supply line 100, a gate terminal coupled to a second input terminal In−, and a drain terminal. Transistors 110 and 112 having their source terminals shorted to one another and having their drain terminals shorted to one another are considered to be connected “in parallel.” The first input terminal In+ can be configured to receive a first waveform 130, whereas the second input terminal In− can be configured to receive a second waveform 132 that is inverted (e.g., phase-shifted by 180 degrees) with respect to waveform 130. Waveforms 130 and 132 are therefore sometimes referred to collectively herein as a “differential” input signal. Input terminals In+ and In− configured to receive a differential signal are sometimes referred to as differential input terminals. Pull-down transistors 110 and 112 can therefore sometimes be referred to herein as differential pull-down transistors or a differential pair of n-type transistors.

At the other end, the pull-up transistors 114 and 116 can be p-type (p-channel) metal-oxide-semiconductor or “PMOS” transistors. Transistor 114 can have a source terminal coupled to a positive power supply line 102 (e.g., a power supply terminal on which a positive power supply voltage Vdd is provided), a gate terminal coupled to the first input terminal In+, and a drain terminal. Similarly, transistor 116 can have a source terminal coupled to the positive power supply line 102, a gate terminal coupled to the second input terminal In−, and a drain terminal. Transistors 114 and 116 having their source terminals shorted to one another and having their drain terminals shorted to one another are considered to be connected “in parallel.” Input terminals In+ and In− are configured to receive differential waveforms 130 and 132. Pull-up transistors 114 and 116 are therefore sometimes be referred to herein as differential pull-up transistors or a differential pair of p-type transistors. The configuration of FIG. 4 in which circuit 62 includes both n-type (pull-down) transistors 110 and 112 and p-type (pull-up) transistors 114 and 116 is sometimes referred to and defined herein as a “complementary” frequency multiplier.

Coil 118, sometimes also referred to as an inductor, can have a first terminal coupled to the drain terminals of the pull-down transistors 110 and 112 and can have a second terminal coupled to the drain terminals of the pull-up transistors 114 and 116. The first terminal of coil 118 can be coupled to a first output terminal Out−, whereas the second terminal of coil 118 can be coupled to a second output terminal Out+. A first output waveform 134 can be produced at output terminal Out−, and a second output waveform 136 can be produced at output terminal Out+. Output waveform 136 can be inverted (e.g., phase-shifted by 180 degrees) with respect to waveform 134. Waveforms 134 and 136 are therefore sometimes referred to collectively herein as a “differential” output signal. Output terminals Out+ and Out− across which a differential output signal is produced are sometimes referred to as differential output terminals. Coil 118 coupled across the output terminals can sometimes be referred to as an output inductor.

Arranged in this way, frequency multiplying circuit 62 can produce a differential output signal having a frequency fout expressed as follows:

$$fout = 1 / [ 2 π * sqrt ( L * C ) ] \qquad ( 1 )$$

where coil 118 has a total inductance of 2L, and where the effective capacitance at each output terminal is equal to C. The capacitance C can be provided by parasitic capacitances associated with the pull-up and pull-down transistors. For example, the capacitance C at output terminal Out− can be at least partially provided by the gate-to-drain capacitance Cgd, the drain-to-source capacitance Cds, and the drain-to-body Cdb capacitance associated with pull-down transistors 110 and 112. At the other end, the capacitance C at output terminal Out+ can be at least partially provided by the gate-to-drain capacitance Cgd, the drain-to-source capacitance Cds, and the drain-to-body Cdb capacitance associated with pull-up transistors 114 and 116. If the transistor parasitic capacitance is insufficient to provide the requisite frequency multiplication, then an output capacitor 120 can optionally be included to provide additional output capacitance so that frequency multiplier 62 can provide the desired frequency fout.

Output coil 118 and the associated output capacitance (e.g., whether the parasitic capacitance at output terminals Out+ and Out− or discrete capacitor 120) can collectively form a resonant circuit having resonant frequency fout. Such inductor-capacitor based resonant circuit is sometimes referred to as a “LC tank” circuit. The frequency of the differential input signal received across input terminals In+ and In− can be referred to as a “fundamental” frequency (see, e.g., frequency f1 in FIG. 3). In accordance with an embodiment, the resonant frequency fout of the differential output signal produced at the output of frequency multiplier 62 can be equal to twice the fundamental frequency, sometimes referred to the second “harmonic” frequency. This second harmonic response can be generated from non-linearities associated with the pull-down and/or pull-up transistors. Frequency fout can be at least greater than 100 MHz, 100-500 MHz, 500-1000 MHz, greater than 1 GHz, 1-5 GHz, 5-10 GHz, greater than 10 GHz, etc. If desired, output frequency fout can be equal to a third harmonic frequency (e.g., three times the fundamental frequency), a fourth harmonic frequency (e.g., four times the fundamental frequency), a fifth harmonic frequency (e.g., five times the fundamental frequency), other harmonic frequency, or some other frequency that is greater than the fundamental frequency.

Frequency multiplying circuit 62 can produce a differential output voltage swing Vout_swing in accordance with the following expression:

$$Vout\_swing = Ids * ( 2 / π ) * Rp * 2 \qquad ( 2 )$$

where Ids represents the drain-to-source current flowing through transistor 110 at a peak of waveform 130, through transistor 112 at a peak of waveform 132, through transistor 114 at a valley of waveform 130, or through transistor 116 at a valley of waveform 132; and where Rp represents the effective parallel resistance of the LC resonant (tank) circuit at the second harmonic (resonant) frequency. As shown by the last term in equation 2, frequency multiplier 62 can be configured to provide two times the output voltage swing compared to a conventional single-ended frequency doubler. This increase in relative voltage swing is due to the differential output scheme between complementary output waveforms 134 and 136. Thus, the output voltage swing can be doubled without increasing the overall current consumption. In other words, current flowing through the pull-down transistors can be “reused” for or recycled into the pull-up transistors to provide a wider voltage swing without increasing the power consumption. Alternatively, the output voltage swing can be kept the same relative to the conventional frequency doubler, but current consumption can be reduced by 50%.

Moreover, as shown in FIG. 4, the output waveforms 134 and 136 can be biased around Vdd/2. For example, coil 118 can optionally have a center tap terminal biased to Vdd/2. Biasing output coil 118 to Vdd/2 instead of shorting one end of the output inductor directly to Vdd in a conventional frequency doubler can help reduce the amount of voltage stress on the pull-down and pull-up transistors, thus further improving the device reliability and robustness of frequency multiplier 62.

The example of FIG. 4 in which the transistors of frequency multiplying circuit 62 are implemented as metal-oxide-semiconductor field-effect transistors (MOSFETs) is illustrative. In general, frequency multiplier 62 can be implemented MOSFETs, bipolar junction transistors (BJTs), insulated-gate bipolar transistors (IGBTs), junction field-effect transistors (JFETs), tunnel field-effect transistors (TFETs), fin field-effect transistors (FinFETs), silicon-on-insulator (SOI) transistors, carbon nanotube transistors, nanowire transistors, a combination of these transistors, and/or other types of transistors.

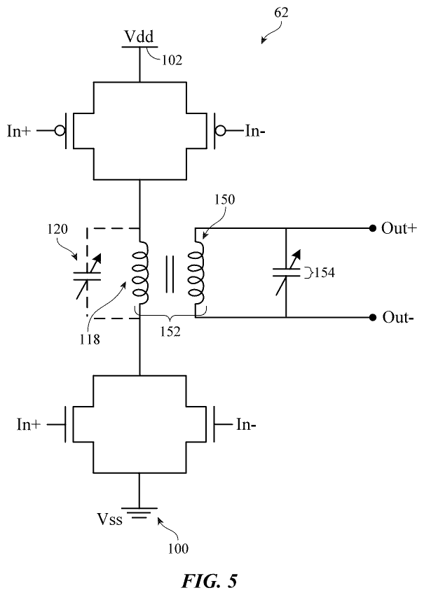

Frequency multiplying circuit 62 of FIG. 4 is capable of providing a differential output without the use of a balun or transformer. Outputting a differential signal instead of a single-ended signal with circuit 62 can be technically advantageous and beneficial to reduce unwanted coupling to nearby circuit components. FIG. 5 shows another embodiment of frequency multiplying circuit 62 that includes an output transformer. As shown in FIG. 5, output coil 118 may serve as a primary coil (winding) of transformer 152. Primary coil 118 can optionally have a center tap terminal biased to Vdd/2. Transformer 152 can further include a secondary coil (winding) 150. Primary coil 118 may be magnetically (inductively) coupled to secondary coil 150. Secondary coil 150 can have a first terminal coupled to output terminal Out+ and a second terminal coupled to output terminal Out−. Transformer 152 coupled to differential output terminals Out+ and Out− can be referred to as an output transformer. In practice, the current driving capabilities of the pull-down transistors and the pull-up transistors might not be perfectly matched and may thus output waveforms that are not perfectly differential or complementary. In such scenarios, use of output transformer 152 can be technically advantageous and beneficial to further reject common mode noise that might be generated from such mismatch between the pull-up and pull-down transistors.

In the example of FIG. 5, frequency multiplying circuit 62 can further include capacitors such as adjustable capacitors 120 and 154. Adjustable capacitor 120 can be coupled across the distal (opposing) terminals of primary coil 118 (e.g., adjustable capacitor 120 may be coupled “in parallel” with primary coil 118). Adjustable capacitor 154 can be coupled across the distal (opposing) terminals of secondary coil 150 (e.g., adjustable capacitor 154 may be coupled “in parallel” with secondary coil 150). Capacitors 120 and 150 can each be an adjustable capacitance implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. The use of adjustable capacitors 120 and 154 can be technically advantageous to provide enhanced flexibility and tunability of the output frequency fout. For example, as shown by equation 1 above, increasing the capacitance values of capacitors 120 and 154 will reduce frequency fout, whereas decreasing the capacitance values of capacitors 120 and 154 will boost frequency fout.

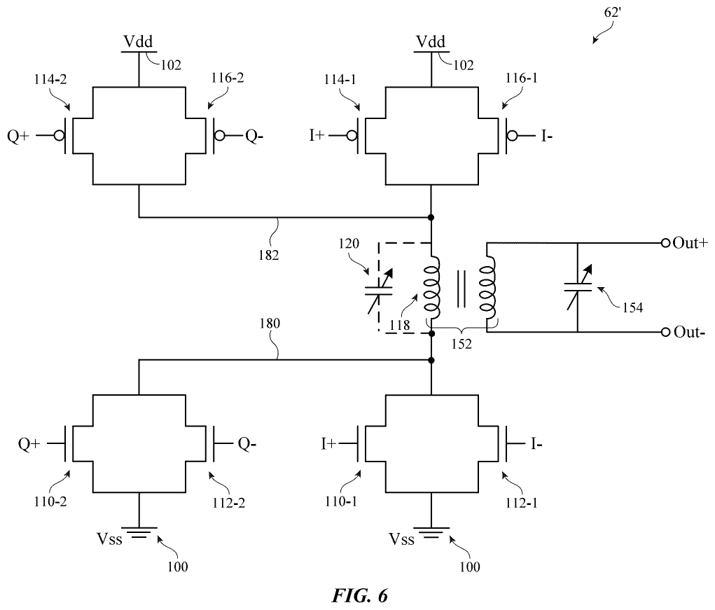

The circuit techniques described in connection with FIGS. 1-5 for implementing a frequency doubler are exemplary and not intended to limit the scope of the present embodiments. FIG. 6 is a circuit diagram of an illustrative frequency quadrupling circuit 62′ in accordance with some embodiments. As shown in FIG. 6, frequency quadrupling circuit 62′ can include coil 118, a first pair of pull-down transistors 110-1 and 112-1 coupled to a first terminal of coil 118, a second pair of pull-down transistors 110-2 and 112-2 coupled to the first terminal of coil 118 via connection path 180, a first pair of pull-up transistors 114-1 and 116-1 coupled to a second terminal of coil 118, and a second pair of pull-up transistors 114-2 and 116-2 coupled to the second terminal of coil 118 via connection path 182. Coil 118 may be a primary coil (winding) of output transformer 152. Adjustable capacitors 120 and 154 can optionally be included for tuning the output frequency of circuit 62′.

Transistors 110-1, 112-1, 114-1, and 116-1 can be configured to receive a first differential input signal, sometimes referred to herein as an “in-phase” (I) signal. In particular, transistors 110-1 and 114-1 have gate terminals configured to receive signal I+, whereas transistors 112-1 and 116-1 have gate terminals configured to receive signal I−, were signal I− is 180 degrees out-of-phase with signal I+.

Transistors 110-2, 112-2, 114-2, and 116-2 can be configured to receive a second differential input signal, sometimes referred to herein as a “quadrature” (Q) signal. In particular, transistors 110-2 and 114-2 have gate terminals configured to receive signal Q+, whereas transistors 112-2 and 116-2 have gate terminals configured to receive signal Q−, were signal Q− is 180 degrees out-of-phase with signal Q+. The quadrature (Q) signal may be 90 degrees out-of-phase with respect to the in-phase (I) signal (e.g., the Q signal may be phase delayed by 90 degrees relative to the I signal, or vice versa). By driving circuit 62′ using two separate differential signals that are 90 degrees phase-shifted with respect to each other in this way, circuit 62′ can produce an output signal having a frequency that is four times the fundamental frequency of the I and Q signals. Circuit 62′ of the type described in connection with FIG. 6 can thus sometimes be referred to as a frequency quadrupler.

Furthermore, the example of FIG. 6 in which circuit 62′ includes two pairs of pull-down (n-type) transistors and two pairs of pull-up (p-type) transistors is illustrative. In general, a frequency multiplying circuit can include one or more pairs of differential pull-down transistors configured to receive separate differential input signals and one or more pairs of differential pull-up transistors configured to receive separate differential input signals.

The methods and operations described above in connection with FIGS. 1-6 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. A frequency multiplying circuit comprising:
a first pull-down transistor configured to receive an input signal having a given frequency;
a first pull-up transistor configured to receive the input signal; and
a coil having a first terminal coupled to the first pull-down transistor and having a second terminal coupled to the first pull-up transistor, wherein the coil is coupled to a differential output at which an output signal having an output frequency that is a multiple of the given frequency is produced.

2. The frequency multiplying circuit of claim 1, wherein the first pull-down transistor comprises an n-type transistor having a drain terminal coupled to the first terminal of the coil, a gate terminal configured to receive the oscillating signal, and a source terminal coupled to a ground power supply line.

3. The frequency multiplying circuit of claim 2, wherein the first pull-up transistor comprises a p-type transistor having a drain terminal coupled to the second terminal of the coil, a gate terminal configured to receive the oscillating signal, and a source terminal coupled to a positive power supply line.

4. The frequency multiplying circuit of claim 1, further comprising:
a second pull-down transistor coupled in parallel with the first pull-down transistor.

5. The frequency multiplying circuit of claim 1, further comprising:
a second pull-up transistor coupled in parallel with the first pull-up transistor.

6. The frequency multiplying circuit of claim 1, further comprising:
a capacitor having a first terminal coupled to the first terminal of the coil and having a second terminal coupled to the second terminal of the coil.

7. The frequency multiplying circuit of claim 1, wherein the first pull-up transistor comprises a source terminal configured to receive power supply voltage, and wherein the coil has a center tap terminal configured to receive a bias voltage equal to half of the power supply voltage.

8. A frequency multiplying circuit configured to multiply a frequency of an oscillating signal, comprising:
a first pull-down transistor configured to receive the oscillating signal;
a first pull-up transistor configured to receive the oscillating signal; and
a transformer having a first terminal coupled to the first pull-down transistor and having a second terminal coupled to the first pull-up transistor.

9. The frequency multiplying circuit of claim 8, further comprising:
a second pull-down transistor coupled in parallel with the first pull-down transistor.

10. The frequency multiplying circuit of claim 9, further comprising:
a second pull-up transistor coupled in parallel with the first pull-up transistor.

11. The frequency multiplying circuit of claim 8, wherein the transformer comprises:
a primary coil having a first terminal coupled to a drain terminal of the first pull-down transistor and having a second terminal coupled to a drain terminal of the first pull-up transistor; and
a secondary coil having a first terminal coupled to a first output terminal and having a second terminal coupled to a second output terminal.

12. The frequency multiplying circuit of claim 11, further comprising:
a first adjustable capacitor coupled across the primary coil.

13. The frequency multiplying circuit of claim 12, further comprising:
a second adjustable capacitor coupled across the secondary coil.

14. The frequency multiplying circuit of claim 11, wherein the first pull-up transistor comprises a source terminal configured to receive power supply voltage, and wherein the primary coil has a center tap terminal configured to receive a bias voltage equal to half of the power supply voltage.

15. Frequency multiplying circuitry comprising:
a coil;
a first pair of pull-down transistors configured to receive a first differential input signal; and
a second pair of pull-down transistors configured to receive a second differential input signal different than the first differential input signal.

16. The frequency multiplying circuitry of claim 15, further comprising:
a first pair of pull-up transistors configured to receive the first differential input signal; and
a second pair of pull-up transistors configured to receive the second differential input signal.

17. The frequency multiplying circuitry of claim 15, wherein the second differential input signal is shifted with respect to the first differential input signal by 90 degrees.

18. The frequency multiplying circuitry of claim 15, wherein the first differential input signal comprises an in-phase signal and wherein the second differential input signal comprises a quadrature signal.

19. The frequency multiplying circuitry of claim 15, further comprising:
an adjustable capacitor coupled across the coil.

20. The frequency multiplying circuitry of claim 15, further comprising:
an additional coil magnetically coupled to the coil; and
an adjustable capacitor coupled across the additional coil.
